(19) United States
(12) Patent Application Publication
(10) Pub. No.: US 2020/0176561 A1
(43) Pub. Date: Jun. 4, 2020

(54) CELLULAR STRUCTURE OF SILICON CARBIDE UMOSFET DEVICE HAVING SURGE VOLTAGE SELF-SUPPRESSION AND SELF-OVERVOLTAGE PROTECTION CAPABILITIES

(71) Applicant: BEIJING CENTURY GOLDRAY SEMICONDUCTOR CO., LTD., Beijing (CN)

(72) Inventors: Jun YUAN, Beijing (CN); Weijiang NI, Beijing (CN); Tianyun Li, Beijing (CN); Mingshan Li, Beijing (CN); Miaoling Xu, Beijing (CN); Jingwei ZHANG, Beijing (CN); Xiping NIU, Beijing (CN); Anxin SUN, Beijing (CN)

(73) Assignee: BEIJING CENTURY GOLDRAY SEMICONDUCTOR CO., LTD., Beijing (CN)

(21) Appl. No.: 16/494,563

(22) PCT Filed: Nov. 30, 2017
(86) PCT No.: PCT/CN2017/113964

§ 371 Date: Sep. 16, 2019

(30) Foreign Application Priority Data
Mar. 23, 2017 (CN) 201710177593.2

(51) Int. Cl. H01L 29/06; H01L 29/16; H01L 29/78

(52) U.S. Cl. CPC H01L 29/0696; H01L 29/7803; H01L 29/7813; H01L 29/1608

(57) ABSTRACT

The present invention discloses a cellular structure of a silicon carbide UMOSFET device having surge voltage self-suppression and self-overvoltage protection capabilities. A p-well region of the cellular structure is divided into three layers; the top layer is on the left and right sides of a U-shaped trench and in contact with the U-shaped trench; the middle layer and the bottom layer are respectively constituted by two parts on the left and right sides of the cellular structure, and the left and right parts of the two are not in contact; the distances between the left and right parts of the middle layer and the vertical axis of the cellular structure are greater than the distances between the left and right parts of the bottom layer and the vertical axis of the cellular structure; that is, a JFET structure is introduced to a drain current path of the cellular structure.

### CROSS-REFERENCE TO RELATED APPLICATIONS

This application claims priority to Chinese Patent Application No. 201710177593.2, filed on Mar. 23, 2017, the contents of which are hereby incorporated by reference.

### TECHNICAL FIELD

The present invention belongs to the technical field of H01L 27/00 semiconductor devices, and specifically relates to a cellular structure of a silicon carbide UMOSFET device having surge voltage self-suppression and self-overvoltage protection capabilities.

### BACKGROUND

The SiC material with excellent properties is attractive for high power, and is one of the ideal materials for high performance power MOSFETs. SiC vertical power MOSFET devices mainly include lateral double-diffused DMOSFETs and vertical gate trench UMOSFETs, as shown in FIG. 1. A planar diffusion technology is used in the DMOSFET structure, a refractory material, such as a polysilicon gate, is used as a mask, and a P-type base region and an N+ source region are defined by the edges of the polysilicon gate. The name of DMOS is derived from this double diffusion process. A surface channel region is formed using the difference in side diffusion of the P-type base region and the N+ source region. The UMOSFET of the vertical gate trench structure is named from a U-shaped trench structure. The U-shaped trench structure is formed by etching reactive ions in a gate region. The U-shaped trench structure has a high channel density (the channel density is defined as the channel width of an active region), which significantly reduces the on-state characteristic resistance of the device.

Planar SiC MOSFETs have been researched in the industry for many years, and some manufacturers have taken the lead in launching commercial products. For ordinary lateral DMOSFET structures, modern technological advances have reached the degree of reducing the cellular size of MOS without reducing the on-resistance, mainly due to the limitation of JFET neck resistance. Even with smaller lithography dimensions, the on-resistance of unit area is also difficult to drop to 2mΩ·cm², whereas the trench structure can effectively solve this problem. The U-shaped trench structure is as shown in FIG. 1 (right), where the conductive channel is changed from the lateral direction to the vertical direction by using a trench etching technology invented in the memory capacitor manufacturing processes, thereby eliminating the JFET neck resistance, greatly increasing the primitive cell density and improving the current handling capability of the power semiconductor when compared to the ordinary structure.

However, SiC UMOSFETs still have several problems in practical fabrication and application: 1) the high electric field in the SiC drift region causes a high electric field on the gate oxide layer, and this problem is exacerbated at the corners of the trench, resulting in quick breakdown of the gate oxide layer under high drain voltage; the electrostatic effect in a harsh environment and the high-voltage spike tolerance in a circuit are poor; 2) since SiC power MOSFETs are mainly applied in the high voltage, high frequency and, high current fields, parasitic parameters in the circuit cause spike burrs such as overshoot in the high-frequency switching process, as shown in FIG. 2, causing transient overvoltage on the current path of the device and increasing the loss of the switching process; or high surge voltage is caused due to the changes in power load, etc., so the surge voltage resistance and overvoltage protection of MOSFETs are also very important. Because the existing MOSFET devices do not have surge voltage self-suppression capability and overvoltage protection capability, complex snubber circuits, surge voltage suppression circuits and overvoltage protection circuits often need to be designed in practical applications, as shown in FIG. 3. However, such external matching suppression and overvoltage protection circuits tend to have time delays, and high-frequency spike voltage surges in the practical switching process are still borne by the devices, sometimes causing breakdown failure of channel regions of the devices, and gradual failure of gate structures and ohmic contact regions of electrodes to cause the reliability problems of the devices.

### SUMMARY

In view of the problems in the prior art, an objective of the present invention is to provide a cellular structure of a silicon carbide UMOSFET device having surge voltage self-suppression and self-overvoltage protection capabilities, which automatically adjusts the on-resistance and self-locking protection effect of the device and can maintain a small cellular size of the device by intentionally introducing a JFET structure to a drain current path.

In order to achieve the above objective, the present invention adopts the following technical solution:

A cellular structure of a silicon carbide UMOSFET device having surge voltage self-suppression and self-overvoltage protection capabilities, a p-well region of the cellular structure is divided into three layers, wherein the top layer is on the left and right sides of a U-shaped trench and in contact with the U-shaped trench; the middle layer and the bottom layer are respectively constituted by two parts on the left and right sides of the cellular structure, and the left and right parts of the two are not in contact; the distances between the left and right parts of the middle layer and the vertical axis of the cellular structure are greater than the distances between the left and right parts of the bottom layer and the vertical axis of the cellular structure; that is, a JFET structure is introduced to a drain current path of the cellular structure.

Compared with the prior art, the present invention has the following technical effects:

By intentionally introducing the JFET structure to the drain current path, a small cellular size of the device can be maintained while the on-resistance and self-locking protection effect of the device are automatically adjusted.

The JFET region intentionally constructed by using a buried P layer can automatically expand depletion regions on two sides under high surge voltage to increase the on-resistance of the JFET region, which is equivalent to a snubber circuit structure automatically suppressing surge spikes; at the same time, when the surge voltage is too high, the depletion regions on the two sides continue to expand and overlap each other to achieve a blocking effect, thereby protecting a gate oxide layer of an internal U-shaped trench gate region, and playing a certain role of spike overvoltage protection.

Although the introduction of JFET increases certain on-resistance, switching buffer and surge voltage self-supression effects are achieved:

The self-suppression resistance of the device to the surge voltage and overvoltage can be increased, and the damage of the device and the reduction of reliability due to actual application of an overvoltage protection circuit and an overcurrent protection circuit are avoided;

At the same time, spike jitter in the circuit switching process is buffered to reduce the switching loss; the snubber circuit in the circuit design and discrete components can be reduced, thereby reducing the cost, reducing the actual module size, and enhance the reliability.

### BRIEF DESCRIPTION OF THE DRAWINGS

FIG. 1 is a schematic diagram showing primitive cell structures of a lateral DMOSFET (left) and a U trench UTMOSFET (right) in the prior art;

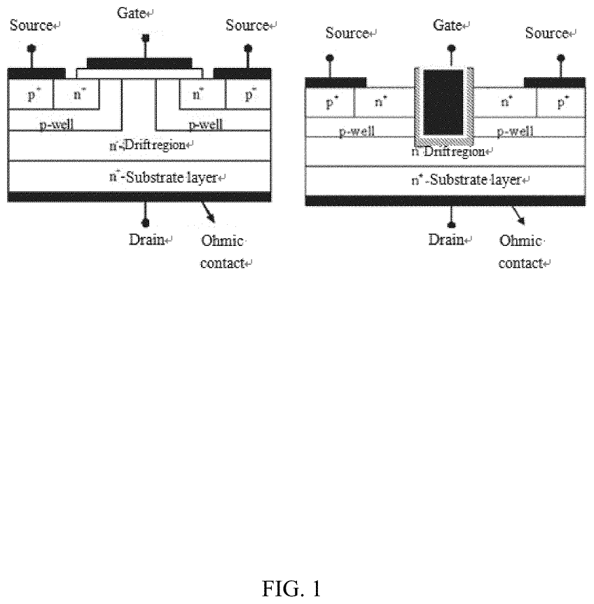

FIG. 2 is a waveform diagram of voltage overshoot and oscillation at the moment of switching of an MOSFET;

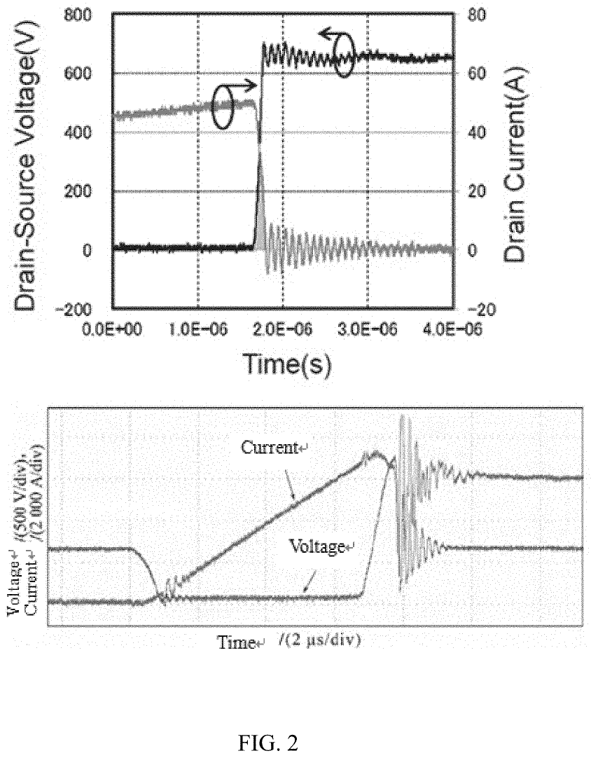

FIG. 3 is a schematic diagram of a cellular structure of a silicon carbide UMOSFET device having surge voltage self-suppression and self-overvoltage protection capabilities according to the present invention;

FIG. 4 is a schematic diagram showing a main current path of the cellular structure of the silicon carbide UMOSFET device having surge voltage self-suppression and self-overvoltage protection capabilities at the moment of turn-on according to the present invention (the right is drawn symmetrically); and

FIG. 5 is a schematic diagram showing equivalent parasitic parameters of the cellular structure of the silicon carbide UMOSFET device having surge voltage self-suppression and self-overvoltage protection capabilities according to the present invention.

### DETAILED DESCRIPTION

The present invention will be illustrated more comprehensively below with reference to the accompanying drawings, in which exemplary embodiments of the present invention are shown. However, the present invention may be embodied in multiple different forms, and should not be understood as being limited to the exemplary embodiments described herein. These embodiments are provided for making the present invention comprehensive and integral and completely delivering the scope of the present invention to those of ordinary skill in the part.

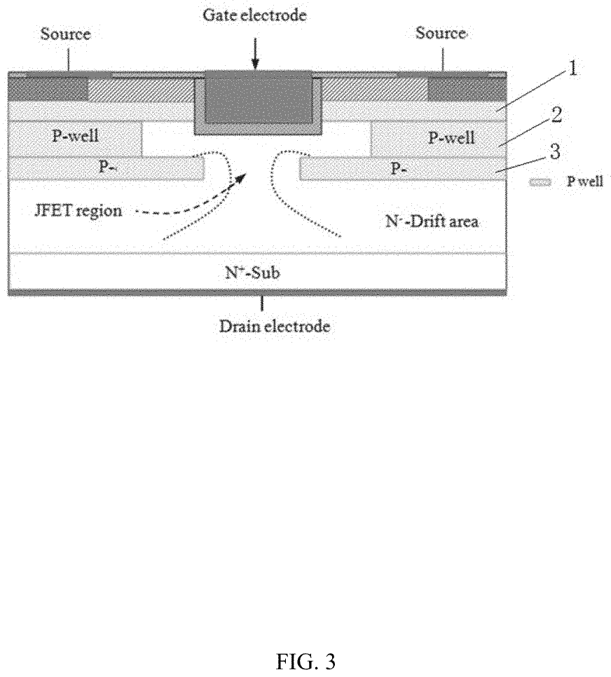

As shown in FIG. 3, the present invention provides a cellular structure of a silicon carbide UMOSFET device having surge voltage self-suppression and self-overvoltage protection capabilities. A p-well region of the cellular structure is divided into three layers, wherein the top layer 1 is on the left and right sides of a U-shaped trench and in contact with the U-shaped trench; the middle layer 2 and the bottom layer 3 are respectively constituted by two parts on the left and right sides of the cellular structure, and the left and right parts of the two are not in contact; the distances between the left and right parts of the middle layer 2 and the vertical axis of the cellular structure are greater than the distances between the left and right parts of the bottom layer 3 and the vertical axis of the cellular structure; that is, a JFET structure is introduced to a drain current path of the cellular structure.

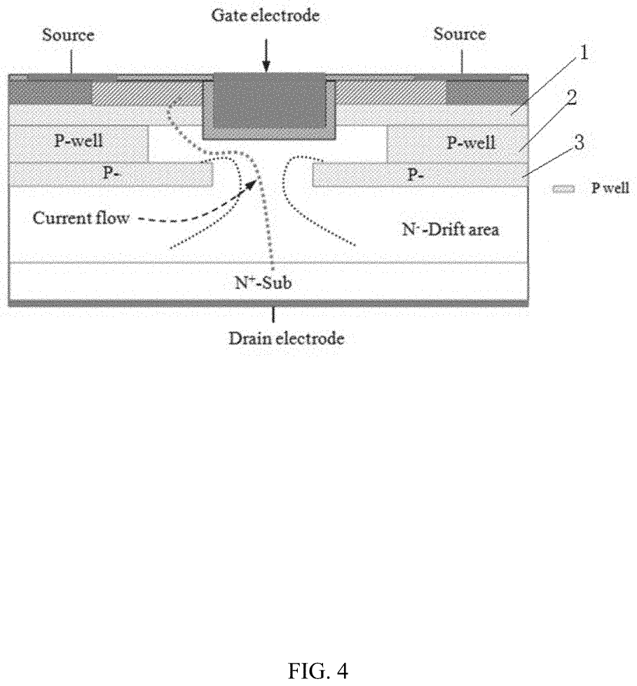

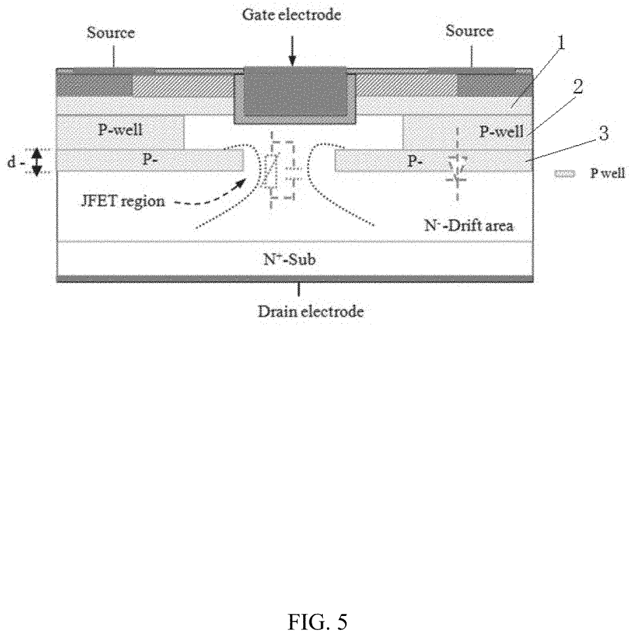

As shown in FIG. 4, when the MOSFET is applied to an actual circuit, current flows through the JFET region at the moment of turn-on of an MOS. Due to the rapid change of current, high-frequency spike voltage is generated in the circuit. At the same time, due to the rapid change of voltage on the current path, the depletion region of the JFET region rapidly expands (or contracts, corresponding to different voltage variations), the JFET at this time is equivalent to a parallel structure of a variable resistor and a junction capacitor, similar to a snubber circuit, as shown in FIG. 5. Through specific circuit application and electrical model simulation of the device, appropriate parasitic parameter values can be obtained by selecting an appropriate thickness d of a buried P region and an appropriate doping concentration, thereby playing a role of effective suppression on voltage spikes and reducing the turn-on loss during actual application to different switching frequency circuit modules.

The above description is only for illustrating the present invention. It should be understood that the present invention is not limited to the above embodiments, and various modifications conforming to the concept of the present invention fall into the protection scope of the present invention.

We claim:

1. A cellular structure of a silicon carbide UMOSFET device having surge voltage self-suppression and self-overvoltage protection capabilities characterized in that, wherein a p-well region of the cellular structure is divided into three layers; the top layer is on the left and right sides of a U-shaped trench and in contact with the U-shaped trench; the middle layer and the bottom layer are respectively constituted by two parts on the left and right sides of the cellular structure, and the left and right parts of the two are not in contact; the distances between the left and right parts of the middle layer and the vertical axis of the cellular structure are greater than the distances between the left and right parts of the bottom layer and the vertical axis of the cellular structure; that is, a JFET structure is introduced to a drain current path of the cellular structure.
